(19) United States
(12) Patent Application Publication
(10) Pub. No.: US 2024/0049455 A1
(43) Pub. Date: Feb. 8, 2024

(54) MEMORY DEVICES AND METHODS FOR FORMING THE SAME

(71) Applicant: YANGTZE MEMORY TECHNOLOGIES CO., LTD., Wuhan (CN)

(72) Inventors: Mingliang Xu, Wuhan (CN); He Chen, Wuhan (CN); Wei Liu, Wuhan (CN)

(21) Appl. No.: 18/225,593

(22) Filed: Jul. 24, 2023

Related U.S. Application Data
(60) Provisional application No. 63/394,952, filed on Aug. 3, 2022.

(30) Foreign Application Priority Data
Jul. 18, 2023 (CN) 202310884134.3

(51) Int. Cl. H10B 12/00

(52) U.S. Cl. CPC H10B 12/482; H10B 12/33; H10B 12/02

(57) ABSTRACT

A semiconductor device includes an array of memory cells, bit lines coupled to the memory cells, and first air gaps. Each of the memory cells includes a vertical transistor. The vertical transistor includes a semiconductor body extends in a first direction. Each of the bit lines is electrically connected to a first end of the semiconductor body. At least one of the first air gaps is between adjacent bit lines.

### CROSS-REFERENCE TO RELATED APPLICATIONS

This application claims the benefit of priorities to C.N. Application No. 202310884134.3, filed on Jul. 18, 2023, and U.S. Provisional Application No. 63/394,952, filed on Aug. 3, 2022, which is hereby incorporated by reference in its entirety.

### BACKGROUND

The present disclosure relates to memory devices and fabrication methods thereof

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

A three-dimensional (3D) memory architecture can address the density limitation in planar memory cells. The 3D memory architecture includes a memory array and peripheral circuits for facilitating operations of the memory array.

### SUMMARY

In one aspect, a semiconductor device includes an array of memory cells. Each of the memory cells includes a vertical transistor. The vertical transistor includes a semiconductor body extends in a first direction. The semiconductor device further includes bit lines coupled to the memory cells. Each of the bit lines is electrically connected to a first end of the semiconductor body. The semiconductor device further includes first air gaps. At least one of the first air gaps is between adjacent bit lines.

In some implementations, at least two of adjacent first air gaps are between adjacent bit lines.

In some implementations, the semiconductor device further includes word lines coupled to the memory cells. Each of the word lines is electrically connected to the gate structure.

In some implementations, each of the first air gaps extends in a second direction, each of the bit lines extends in the second direction, and each of the word lines extends in a third direction. The first direction is perpendicular to the second direction, and the second direction is perpendicular to the third direction.

In some implementations, the semiconductor device further includes a first dielectric layer. At least a portion of the first dielectric layer is between adjacent bit lines.

In some implementations, the semiconductor device further includes a first dielectric layer. At least a portion of the first dielectric layer is between two adjacent first air gaps.

In some implementations, the semiconductor device further includes a first dielectric layer. At least one of the first air gaps is encapsulated by the first dielectric layer.

In some implementations, the semiconductor device further includes second dielectric layers extending in the first direction. Each of the second dielectric layers is between two adjacent semiconductor bodies.

In some implementations, the semiconductor device further includes a first dielectric layer, and second dielectric layers. At least a portion of the first dielectric layer is between adjacent second dielectric layers.

In some implementations, at least one of the first air gaps is encapsulated by the first dielectric layer and one of the second dielectric layers.

In some implementations, the semiconductor device further includes a first dielectric layer. Only one first air gap is between adjacent bit lines, and the first air gap is encapsulated by the first dielectric layer.

In some implementations, each of the memory cells further includes a storage structure coupled to a second end of the semiconductor body.

In some implementations, the vertical transistor further includes a gate structure in contact with a first side of the semiconductor body.

In another aspect, a method for manufacturing a semiconductor device includes removing a portion of a semiconductor stack to form first trenches in a first direction and semiconductor bodies, depositing a first dielectric material to form a first dielectric layer on a bottom surface and sidewalls of the first trenches, depositing a second dielectric material in the first trenches to form a second dielectric layer to a predetermined height of the first trenches, filling up the first trenches with a first oxide material to form a first oxide layer in the first trenches, applying an etching process to expose the semiconductor body, removing the second dielectric layer to form third trenches, and depositing the first dielectric material to form first air gaps.

In some implementations, the method further includes removing a portion of the first oxide layer to form second trenches, and depositing a first metal material on the first oxide layer in the second trenches to form word line layers.

In some implementations, the method further includes removing a portion of the semiconductor bodies to form fourth trenches, and depositing a second metal material in the fourth trenches to form bit line layers.

In some implementations, the predetermined height of the first trenches is larger than a first depth of the bit line layers.

In some implementations, at least one of the first air gaps is between adjacent bit lines.

In some implementations, removing the second dielectric layer to form third trenches includes removing the second dielectric layer to a second depth. The second depth is larger than a first depth of the bit line layers.

In some implementations, at least one of the first air gaps is encapsulated by the first dielectric layer, the semiconductor body, and the bit line layers.

In some implementations, the method further includes forming capacitors coupled to the semiconductor body after depositing the first metal material on the first oxide layer in the second trenches to form the word line layers.

In some implementations, the method further includes depositing the first dielectric material on the capacitors to form an interlayer, and bonding to a carrier substrate via the interlayer after forming the capacitors.

In some implementations, the method further includes thinning the semiconductor stack to expose the second dielectric layer and the semiconductor body after bonding to the carrier substrate.

In still another aspect, a method for manufacturing a semiconductor device includes removing a portion of a semiconductor stack to form first trenches in a first direction and semiconductor bodies, depositing a first dielectric material to form a first dielectric layer on a bottom surface and sidewalls of the first trenches, depositing a second dielectric material to form a second dielectric layer on the first dielectric layer, filling up the first trenches with a first oxide material to form a first oxide layer in the first trenches, applying an etching process to expose the semiconductor body, removing a portion of the second dielectric layer to form third trenches, and depositing the first dielectric material to form first air gaps.

In some implementations, the method further includes removing a portion of the first oxide layer to form second trenches, and depositing a first metal material on the first oxide layer in the second trenches to form word line layers.

In some implementations, the method further includes forming capacitors coupled to the semiconductor body after depositing the first metal material on the first oxide layer in the second trenches to form the word line layers.

In some implementations, the method further includes depositing the first dielectric material on the capacitors to form an interlayer, and bonding to a carrier substrate via the interlayer after forming the capacitors.

In some implementations, the method further includes thinning the semiconductor stack to expose the second dielectric layer and the semiconductor body after bonding to the carrier substrate.

In some implementations, the method further includes removing a portion of the semiconductor bodies to form fourth trenches, and depositing a second metal material in the fourth trenches to form bit line layers.

In some implementations, at least two of the first air gaps is between adjacent bit lines.

In some implementations, removing a portion of the second dielectric layer to form third trenches includes removing the second dielectric layer to a second depth. The second depth is larger than a first depth of the bit line layers.

In some implementations, at least two of the first air gaps are encapsulated by the first dielectric layer, the semiconductor body, and the bit line layers.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a schematic view of a cross-section of a memory device, according to some aspects of the present disclosure.

FIG. 1B illustrates a schematic view of a cross-section of another memory device, according to some aspects of the present disclosure.

FIG. 2 illustrates a schematic diagram of a memory device including peripheral circuits and an array of memory cells each having a vertical transistor, according to some aspects of the present disclosure.

FIG. 3 illustrates a schematic circuit diagram of a memory device including peripheral circuits and an array of dynamic random-access memory (DRAM) cells, according to some aspects of the present disclosure.

FIG. 4A illustrates a schematic diagram of a plan view of a memory device, according to some aspects of the present disclosure.

FIGS. 4B and 4C illustrate schematic diagrams of cross-sections of a memory device, according to some aspects of the present disclosure.

FIG. 5A illustrates a schematic diagram of a plan view of a memory device, according to some aspects of the present disclosure.

FIGS. 5B and 5C illustrate schematic diagrams of cross-sections of a memory device, according to some aspects of the present disclosure.

FIGS. 6A-6K illustrate a fabrication process for forming a memory device including vertical transistors, according to some aspects of the present disclosure.

FIGS. 7A-7K illustrate a fabrication process for forming a memory device including vertical transistors, according to some aspects of the present disclosure.

FIG. 8 illustrates a flowchart of a method for forming a memory device, according to some aspects of the present disclosure.

FIG. 9 illustrates a flowchart of a method for forming a memory device, according to some aspects of the present disclosure.

FIG. 10 illustrates a block diagram of an example system having a memory device, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some memory devices, such as dynamic random-access memory (DRAM), phase change memory (PCM), and ferroelectric random access memory (FRAM). However, the planar transistors commonly used in existing memory cells usually have a horizontal structure with buried word lines in the substrate and bit lines above the substrate. Since the source and drain of a planar transistor are disposed laterally at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield. Moreover, because the bit lines and the storage units (e.g., capacitors or PCM elements) are arranged on the same side of the planar transistors (above the transistors and substrate), the bit line process margin is limited by the storage units, and the coupling capacitance between the bit lines and storage units, such as capacitors, are increased. Planar transistors may also suffer from a high leakage current as the saturated drain current keeps increasing, which is undesirable for the performance of memory devices.

On the other hand, the memory cell array and the peripheral circuits for controlling the memory cell array are usually arranged side-by-side in the same plane. As the number of memory cells keeps increasing, to maintain the same chip size, the dimensions of the components in the memory cell array, such as transistors, word lines, and/or bit lines, need to keep decreasing in order not to significantly reduce the memory cell array efficiency.

Furthermore, according to some implementations, building up a 3D memory architecture may further reduce the need for additional storage node contact (SNC) between adjacent bit lines. The adjacent bit lines are directly coupled to each other via dielectric materials, thereby increasing the coupling capacitance between adjacent bit lines. These increased coupling capacitances may reduce the sensing margin during the read operation and also reduce the retention time of the memory cells.

To address one or more of the aforementioned issues, the present disclosure introduces a solution in which vertical transistors replace the planar transistors as the switch and selecting devices in a memory cell array of memory devices (e.g., DRAM, PCM, and FRAM). Compared with planar transistors, the vertically arranged transistors (e.g., the drain and source are overlapped in the plan view) can reduce the area of the transistor as well as simplify the layout of the interconnect structures, e.g., metal wiring the word lines and bit lines, which can reduce the fabrication complexity and improve the yield. For example, the pitches of word lines and/or bit lines can be reduced for ease of fabrication. The vertical structures of the transistors also allow the bit lines and storage units, such as capacitors, to be arranged on opposite sides of the transistors in the vertical direction (e.g., one above and one below the transistors), such that the process margin of the bit lines can be increased and the coupling capacitance between the bit lines and the storage units can be reduced.

According to some aspects of the present disclosure, air gaps are formed between the adjacent bit lines in multiple ways (e.g., single air gaps or double air gaps). These air gaps may reduce the coupling capacitances between adjacent bit lines, thereby increasing the sensing margin during the read operation and increasing the retention time of the memory cells. According to some aspects of the present disclosure, the fabrication process utilizes the self-align technique during the forming of bit lines to form trenches for air gaps, thereby reducing the complexity of forming the air gaps between adjacent bit lines.

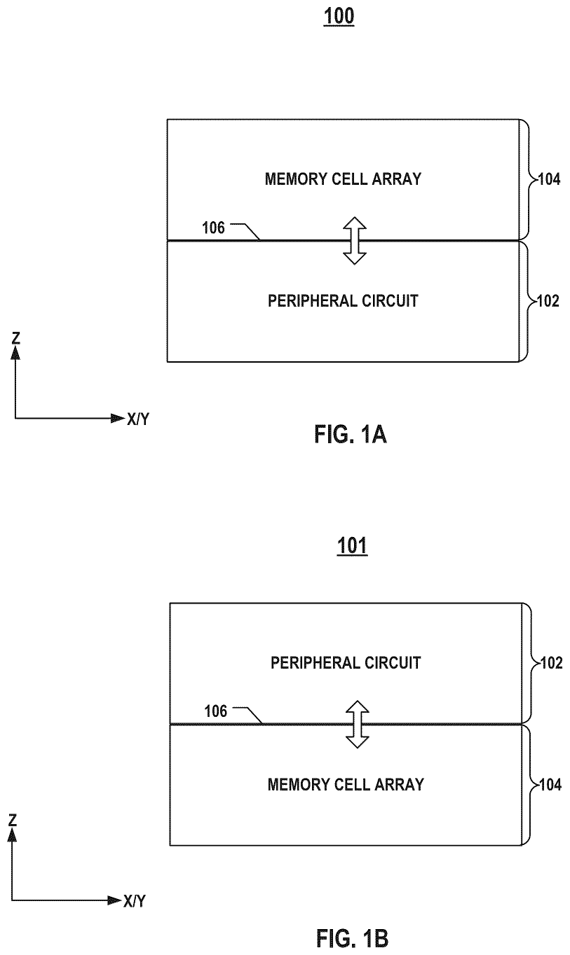

FIG. 1A illustrates a schematic view of a cross-section of a memory device 100, according to some aspects of the present disclosure. Memory device 100 represents an example of a bonded chip. The components of memory device 100 (e.g., memory cell array and peripheral circuits) can be formed separately on different substrates and then jointed to form a bonded chip. Memory device 100 can include a first semiconductor structure 102 including the peripheral circuits of a memory cell array. Memory device 100 can also include a second semiconductor structure 104 including the memory cell array. The peripheral circuits (a.k.a. control and sensing circuits) can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in first semiconductor structure 102 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

As shown in FIG. 1A, memory device 100 can also include second semiconductor structure 104 including an array of memory cells (memory cell array) that can use transistors as the switch and selecting devices. In some implementations, the memory cell array includes an array of DRAM cells. For ease of description, a DRAM cell array may be used as an example for describing the memory cell array in the present disclosure. But it is understood that the memory cell array is not limited to DRAM cell array and may include any other suitable types of memory cell arrays that can use transistors as the switch and selecting devices, such as PCM cell array, static random-access memory (SRAM) cell array, FRAM cell array, resistive memory cell array, magnetic memory cell array, spin transfer torque (STT) memory cell array, to name a few, or any combination thereof.

Second semiconductor structure 104 can be a DRAM device in which memory cells are provided in the form of an array of DRAM cells. In some implementations, each DRAM cell includes a capacitor for storing a bit of data as a positive or negative electrical charge as well as one or more transistors (a.k.a. pass transistors) that control (e.g., switch and selecting) access to it. In some implementations, each DRAM cell is a one-transistor, one-capacitor (1T1C) cell. Since transistors always leak a small amount of charge, the capacitors will slowly discharge, causing information stored in them to drain. As such, a DRAM cell has to be refreshed to retain data, for example, by the peripheral circuit in first semiconductor structure 102, according to some implementations.

As shown in FIG. 1A, memory device 100 further includes a bonding interface 106 vertically between (in the vertical direction, e.g., the Z-direction in FIG. 1A) first semiconductor structure 102 and second semiconductor structure 104. As described below in detail, first and second semiconductor structures 102 and 104 can be fabricated separately (and in parallel in some implementations) such that the thermal budget of fabricating one of first and second semiconductor structures 102 and 104 does not limit the processes of fabricating another one of first and second semiconductor structures 102 and 104. Moreover, a large number of interconnects (e.g., bonding contacts) can be formed through bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory cell array in second semiconductor structure 104 and the peripheral circuits in first semiconductor structure 102 can be performed through the interconnects (e.g., bonding contacts) across bonding interface 106. By vertically integrating first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of another example memory device 101, according to some implementations. Different from memory device 100 in FIG. 1A, in which second semiconductor structure 104 including the memory cell array is above first semiconductor structure 102 including the peripheral circuits, in memory device 101 in FIG. 1B, first semiconductor structure 102 including the peripheral circuit is above second semiconductor structure 104 including the memory cell array. Nevertheless, bonding interface 106 is formed vertically between first and second semiconductor structures 102 and 104 in memory device 101, and first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory cell array in second semiconductor structure 104 and the peripheral circuits in first semiconductor structure 102 can be performed through the interconnects (e.g., bonding contacts) across bonding interface 106.

It is noted that X, Y, and Z axes are included in FIGS. 1A and 1B to further illustrate the spatial relationship of the components in memory devices 100 and 101. The substrate of the memory device includes two lateral surfaces extending laterally in the X-Y plane: a top surface on the front side of the wafer on which the semiconductor devices can be formed, and a bottom surface on the backside opposite to the front side of the wafer. The Z-axis is perpendicular to both the X and Y axes. As used herein, whether one component (e.g., a layer or a device) is “on,” “above,” or “below” another component (e.g., a layer or a device) of the memory device is determined relative to the substrate of the memory device in the Z-direction (the vertical direction perpendicular to the X-Y plane, e.g., the thickness direction of the substrate) when the substrate is positioned in the lowest plane of the memory device in the Z-direction. The same notion for describing the spatial relationships is applied throughout the present disclosure.

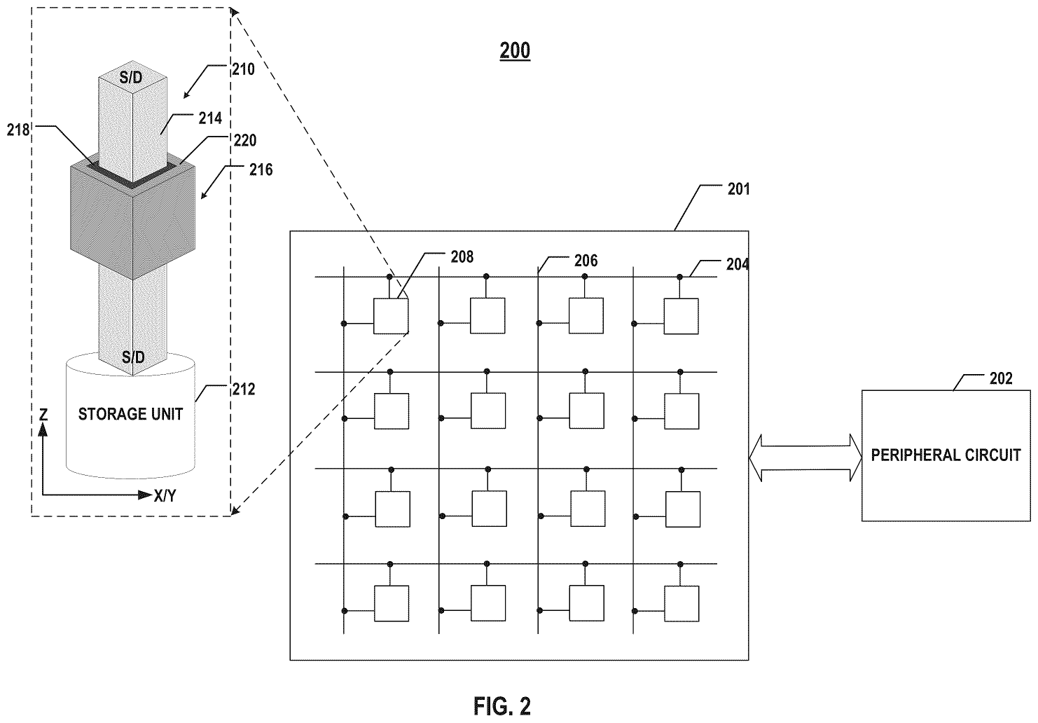

FIG. 2 illustrates a schematic diagram of a memory device 200 including peripheral circuits and an array of memory cells each having a vertical transistor, according to some aspects of the present disclosure. Memory device 200 can include a memory cell array 201 and peripheral circuits 202 coupled to memory cell array 201. Memory device 200 can be or include a semiconductor device or a semiconductor array wafer. In some implementations, memory cell array 201 is included in the semiconductor device or the semiconductor array wafer. Memory devices 100 and 101 may be examples of memory device 200 in which memory cell array 201 and peripheral circuits 202 may be included in second and first semiconductor structures 104 and 102, respectively. Memory cell array 201 can be a semiconductor device or a semiconductor array wafer. Memory cell array 201 can be any suitable memory cell array in which each memory cell 208 includes a vertical transistor 210 and a storage unit 212 coupled to vertical transistor 210. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Memory device 200 can include word lines 204 coupling peripheral circuits 202 and memory cell array 201 for controlling the switch of vertical transistors 210 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

Consistent with the scope of the present disclosure, vertical transistors 210, such as vertical metal-oxide-semiconductor field-effect transistors (MOSFETs), can replace the planar transistors as the pass transistors of memory cells 208 to reduce the area occupied by the pass transistors, the coupling capacitance, as well as the interconnect routing complexity, as described below in detail. As shown in FIG. 2, in some implementations, different from planar transistors in which the active regions are formed in the substrates, vertical transistor 210 includes a semiconductor body 214 extending vertically (in the Z-direction) above the substrate (not shown). That is, semiconductor body 214 can extend above the top surface of the substrate to allow channels to be formed not only at the top surface of semiconductor body 214, but also at one or more side surfaces thereof. As shown in FIG. 2, for example, semiconductor body 214 can have a cuboid shape to expose four sides thereof. It is understood that semiconductor body 214 may have any suitable 3D shape, such as polyhedron shapes or a cylinder shape. That is, the cross-section of semiconductor body 214 in the plan view (e.g., in the X-Y plane) can have a square shape, a rectangular shape (or a trapezoidal shape), a circular (or an oval shape), or any other suitable shapes. It is understood that consistent with the scope of the present disclosure, for semiconductor bodies that have a circular or oval shape of their cross-sections in the plan view, the semiconductor bodies may still be considered as having multiple sides, such that the gate structures is in contact with more than one side of the semiconductor bodies. As described below with respect to the fabrication process, semiconductor body 214 can be formed from the substrate (e.g., by etching or epitaxy) and thus, has the same semiconductor material (e.g., silicon crystalline silicon) as the substrate (e.g., a silicon substrate).

As shown in FIG. 2, vertical transistor 210 can also include a gate structure 216 in contact with one or more sides of semiconductor body 214, e.g., in one or more planes of the side surface(s) of the active region. In other words, the active region of vertical transistor 210, e.g., semiconductor body 214, can be at least partially surrounded by gate structure 216. Gate structure 216 can include a gate dielectric 218 over one or more sides of semiconductor body 214, e.g., in contact with four side surfaces of semiconductor body 214, as shown in FIG. 2. Gate structure 216 can also include a gate electrode 220 over and in contact with gate dielectric 218. Gate dielectric 218 can include any suitable dielectric materials, such as silicon oxide, silicon nitride, silicon oxynitride, or high-k dielectrics. For example, gate dielectric 218 may include silicon oxide, which is a form of gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, which is a form of a gate poly. In some implementations, gate electrode 220 includes multiple conductive layers, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the Z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the Z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be in contact with more than one side of semiconductor body 214 (e.g., four sides in FIG. 2) to form more than one gate, such that more than one channel can be formed between the source and drain in operation. That is, different from the planar transistor that includes only a single planar gate (and resulting in a single planar channel), vertical transistor 210 shown in FIG. 2 can include multiple vertical gates on multiple sides of semiconductor body 214 due to the 3D structure of semiconductor body 214 and gate structure 216 that surrounds the multiple sides of semiconductor body 214. As a result, compared with planar transistors, vertical transistor 210 shown in FIG. 2, can have a larger gate control area to achieve better channel control with a smaller subthreshold swing. Since the channel is fully depleted, the leakage current (Ioff) of vertical transistor 210 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 210 is shown as a multi-gate transistor in FIG. 2, the vertical transistors disclosed herein may also include single-gate transistors as described below in detail. That is, gate structure 216 may be in contact with a single side of semiconductor body 214, for example, for the purpose of increasing the transistor and memory cell density. It is also understood that although gate dielectric 218 is shown as being separate (a separate structure) from other gate dielectrics of adjacent vertical transistors (not shown), gate dielectric 218 may be part of a continuous dielectric layer having multiple gate dielectrics of vertical transistors.

In planar transistors and some lateral multiple-gate transistors (e.g., FinFET), the active regions, such as semiconductor bodies (e.g., Fins), extend laterally (in the X-Y plane), and the source and the drain are disposed at different locations in the same lateral plane (the X-Y plane). In contrast, in vertical transistor 210, semiconductor body 214 extends vertically (in the Z-direction), and the source and the drain are disposed in the different lateral planes, according to some implementations. In some implementations, the source and the drain are formed at two ends of semiconductor body 214 in the vertical direction (the Z-direction), respectively, thereby being overlapped in the plan view. As a result, the area (in the X-Y plane) occupied by vertical transistor 210 can be reduced compared with planar transistors and lateral multiple-gate transistors. Also, the metal wiring coupled to vertical transistors 210 can be simplified as well since the interconnects can be routed in different planes. For example, bit lines 206 and storage units 212 may be formed on opposite sides of vertical transistor 210. In one example, bit line 206 may be coupled to the source or the drain at the upper end of semiconductor body 214, while storage unit 212 may be coupled to the other source or the drain at the lower end of semiconductor body 214.

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210.

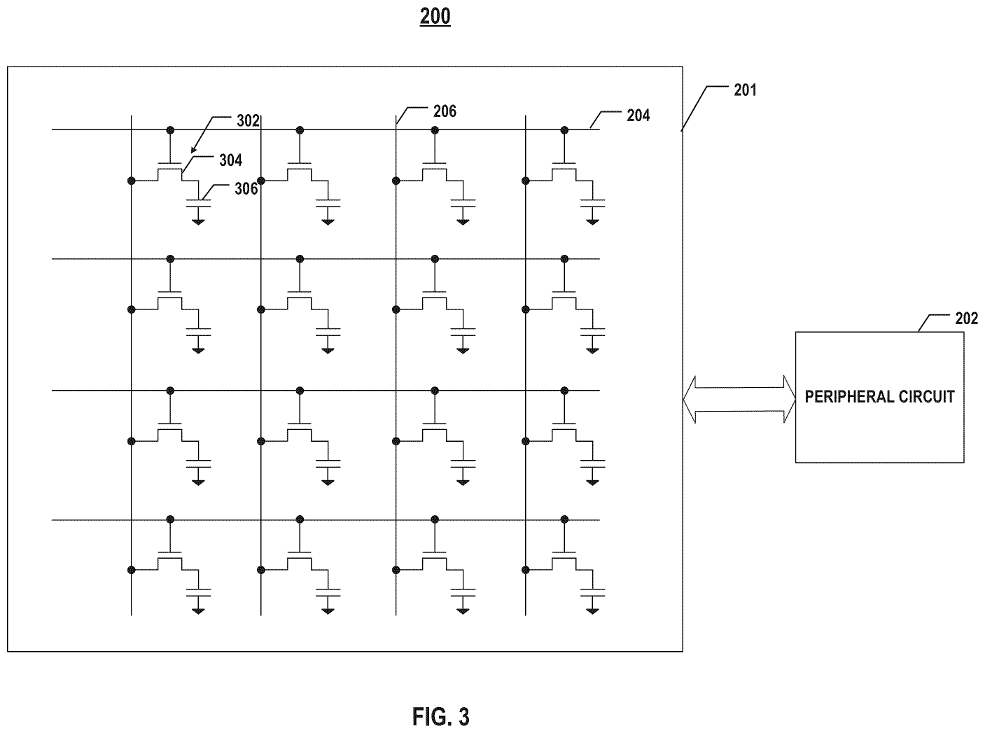

FIG. 3 illustrates a schematic diagram of memory device 200 including peripheral circuits and an array of memory cells each having a vertical transistor, according to some aspects of the present disclosure. In some implementations as shown in FIG. 3, each memory cell 208 is a DRAM cell 302 including a transistor 304 (e.g., implementing using vertical transistors 210 in FIG. 2) and a capacitor 306 (e.g., an example of storage unit 212 in FIG. 2). The gate of transistor 304 (e.g., corresponding to gate electrode 220) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground.

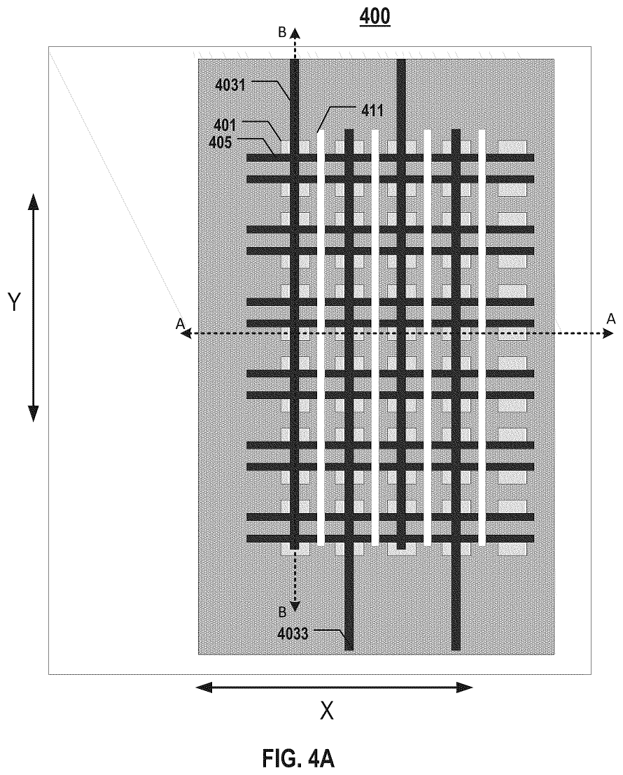

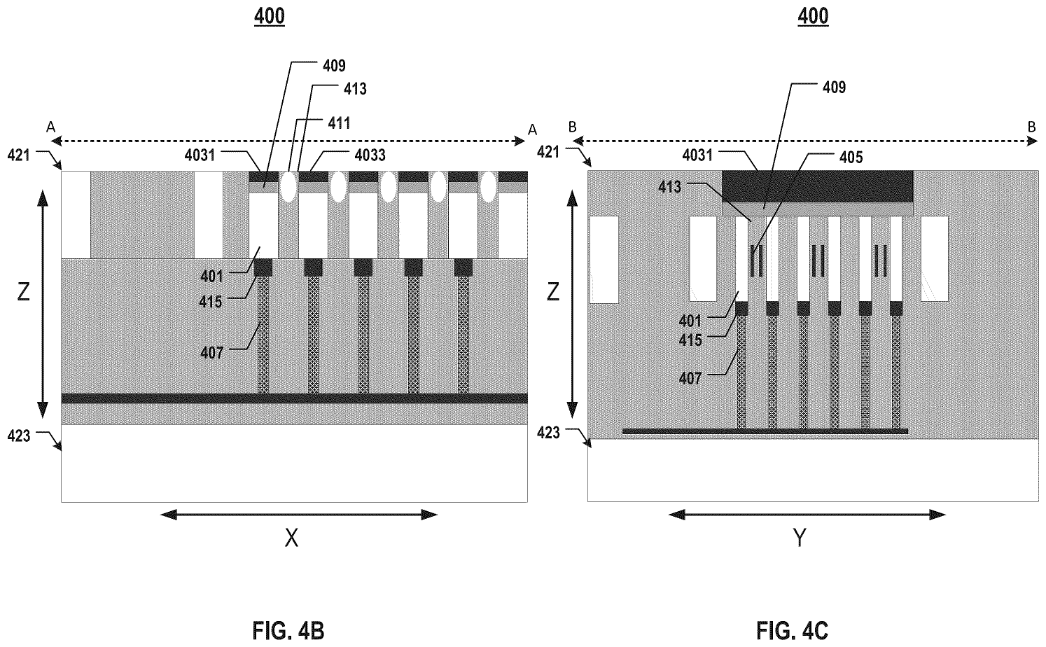

FIG. 4A illustrates a schematic diagram of a plan view of a memory device 400, according to some aspects of the present disclosure. And FIGS. 4B and 4C illustrate schematic diagrams of cross-sections of a memory device, according to some aspects of the present disclosure. In particular, FIG. 4B illustrates a schematic diagram of a cross-section of a memory device along the AA plane as shown in FIG. 4A. FIG. 4C illustrates a schematic diagram of a cross-section of a memory device along the BB plane as shown in FIG. 4B.

As shown in FIG. 4A, memory device 400 includes an array of memory cells (e.g., memory cells 208 in FIG. 2) formed in a second semiconductor structure 421 (e.g., second semiconductor structure 104 in FIG. 1) including the memory cell array. Each of the memory cells includes a vertical transistor (e.g., vertical transistor 210 in FIG. 2) and a storage structure (e.g., storage unit 212 in FIG. 2) coupled to the vertical transistor in a first direction (e.g., the vertical direction or the Z-direction). The vertical transistor includes a semiconductor body 401 (e.g., semiconductor body 214 in FIG. 2) extending in the first direction and a gate structure (e.g., gate structure 216 in FIG. 2) in contact with a first side of semiconductor body 401. As mentioned above, the gate structure can be in contact with more than one side of the semiconductor body (e.g., four sides in FIG. 2) to form more than one gate, such that more than one channel can be formed between the source and drain in operation.

Memory device 400 may further include bit lines (e.g., a first bit line 4031 and a second bit line 4033) coupled to the memory cells. Each of the bit lines is electrically connected to a first end of the semiconductor body (e.g., in the opposite direction toward the storage units). The first end of the semiconductor body can be, for instance, the source end of the semiconductor body. Memory device 400 may include first air gaps 411. At least one of first air gaps 411 is between adjacent bit lines (e.g., first bit line 4031 and second bit line 4033) along the X-direction. As mentioned above, these air gaps between adjacent the bit lines may reduce the coupling capacitance between adjacent bit lines, thereby increasing the sensing margin during the read operation and increasing the retention time of the memory cells. The bit lines can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, the bit lines may include tungsten.

Memory device 400 may further includes word lines 405 coupled to the memory cells. Each of word lines 405 is electrically connected to the gate structure (e.g., gate structure 216 in FIG. 2) in contact with the first side of semiconductor body 401. In some implementations, each of first air gaps 411, as shown in FIG. 4A, extends in a second direction (e.g., the Y-direction). Each of bit lines (e.g., first bit line 4031 and second bit line 4033) extends in the second direction. Each of word lines 405 extends in a third direction (e.g., the X-direction). The first direction is perpendicular to the second direction, and the second direction is perpendicular to the third direction. The word lines can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, the word lines may include titanium nitride.

Memory device 400 may further include a first dielectric layer 413. As shown in FIGS. 4B and 4C, at least a portion of first dielectric layer 413 is between the adjacent bit lines, and at least one of first air gaps 411 is encapsulated by a portion of first dielectric layer 413. That is, some portions of first dielectric layer 413 may encapsulate first air gaps 411 while some portions of first dielectric layer 413 may have openings on top or side of first air gaps 411. In some implementations, first air gaps 411 are at least partially surrounded by first dielectric layer 413. In some implementations, only one first air gap 411 is between two adjacent bit lines. First air gap 411, in some implementations, may extend in the first direction (e.g., the Z-direction) in the same or similar depth of the bit lines. First air gap 411, in some implementations, may extend in the first direction (e.g., the Z-direction) to the same or similar depth of semiconductor body 401 such that first air gaps 411 may be between adjacent semiconductor bodies 401 along the X-direction. In some implementations, first dielectric layer 413 can include any suitable dielectric materials, such as silicon oxide, silicon nitride, silicon oxynitride, or high-k dielectrics. For example, first dielectric layer 413 may include silicon oxide.

Memory device 400, as shown in FIGS. 4B and 4C, may further include bit line contacts 409. Each of bit line contacts 409 is between each of bit lines (e.g., first bit line 4031 and second bit line 4033) and a corresponding semiconductor body 401. Bit line contacts 409 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, bit line contacts 409 may include doped polysilicon.

Memory device 400, as shown in FIG. 4C, may further include storage units 407 (e.g., storage unit 212 in FIG. 2). Each of storage units 407 is coupled to a second end of a corresponding semiconductor body 401 (opposite to the first end of semiconductor body 401 along the Z-direction). The second end of the semiconductor body can be, for instance, the drain end of the semiconductor body. In some implementations, each of storage units 407 is coupled to the second end of the corresponding semiconductor body 401 via a storage unit contact 415.

As shown in FIG. 4C, memory device 400 includes a first semiconductor structure 423 (e.g., first semiconductor structure 102 in FIG. 1) including the peripheral circuits of the memory cell array coupled to second semiconductor structure 421. A bonding interface can be formed between first semiconductor structure 423 and second semiconductor structure 421. In some implementations, the bonding interface may be a boundary between the memory cell array in second semiconductor structure 421 and the peripheral circuit in first semiconductor structure 423.

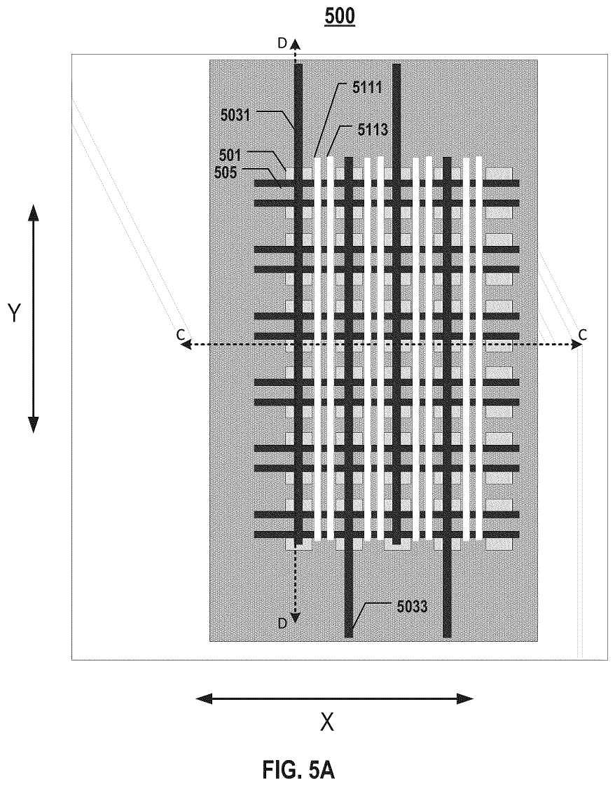

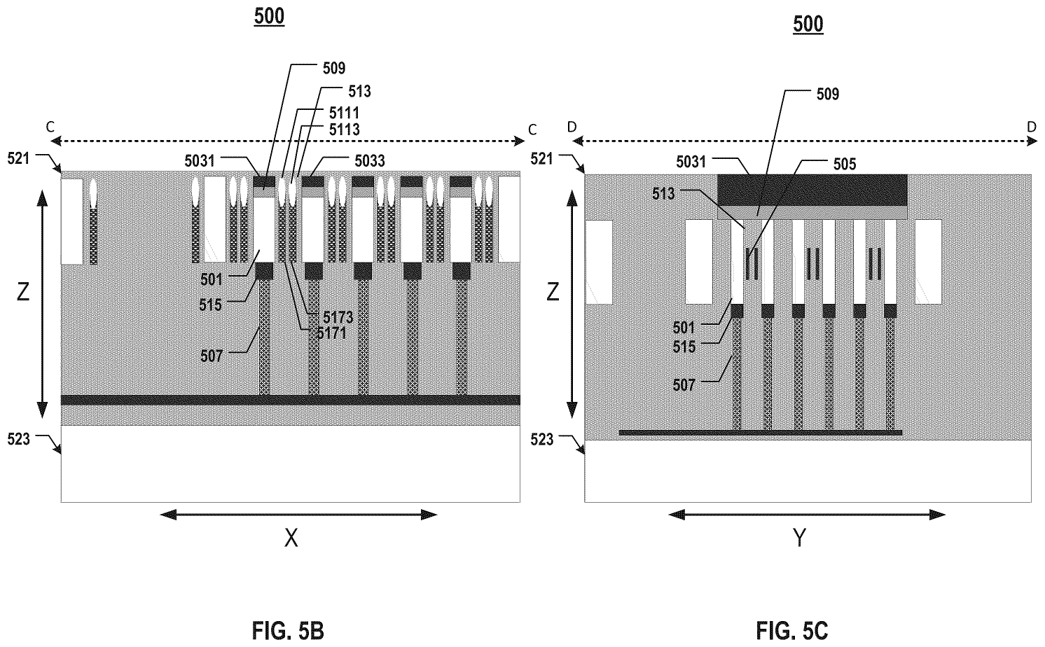

FIG. 5A illustrates a schematic diagram of a plan view of a memory device 500, according to some aspects of the present disclosure. And FIGS. 5B and 5C illustrate schematic diagrams of cross-sections of a memory device, according to some aspects of the present disclosure. In particular, FIG. 5B illustrates a schematic diagram of a cross-section of a memory device along the CC plane as shown in FIG. 5A. FIG. 5C illustrates a schematic diagram of a cross-section of a memory device along the DD plane as shown in FIG. 5B.

As shown in FIG. 5A, memory device 500 includes an array of memory cells (e.g., memory cells 208 in FIG. 2) formed in a second semiconductor structure 521 (e.g., second semiconductor structure 104 in FIG. 1) including the memory cell array. Each of the memory cells includes a vertical transistor (e.g., vertical transistor 210 in FIG. 2) and a storage structure (e.g., storage unit 212 in FIG. 2) coupled to the vertical transistor in a first direction (e.g., the vertical direction or the Z-direction). The vertical transistor includes a semiconductor body 501 (e.g., semiconductor body 214 in FIG. 2) extending in the first direction and a gate structure (e.g., gate structure 216 in FIG. 2) in contact with a first side of semiconductor body 501. As mentioned above, the gate structure can be in contact with more than one side of the semiconductor body (e.g., four sides in FIG. 2) to form more than one gate, such that more than one channel can be formed between the source and drain in operation.

Memory device 500 may further include bit lines (e.g., a first bit line 5031 and a second bit line 5033) coupled to the memory cells. Each of the bit lines is electrically connected to a first end of semiconductor body 501 (e.g., in an opposite direction toward the storage units). The first end of semiconductor body 501 can be, for instance, the source end of semiconductor body 501. Memory device 500 may include a pair of first air gaps 5111 and 5113. At least a portion of the pair of first air gaps 5111 and 5113 is between adjacent bit lines (e.g., first bit line 5031 and second bit line 5033) along the X-direction. It is noted that memory device 500 may include more than two first air gaps between adjacent bit lines. As mentioned above, these air gaps between adjacent the bit lines may reduce the coupling capacitance between adjacent bit lines, thereby increasing the sensing margin during the read operation and increasing the retention time of the memory cells. The bit lines can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, the bit lines may include tungsten.

Memory device 500 may further include word lines 505 coupled to the memory cells. Each of word lines 505 is electrically connected to the gate structure (e.g., gate structure 216 in FIG. 2) in contact with the first side of semiconductor body 501. In some implementations, each pair of first air gaps 5111 and 5113, as shown in FIG. 5A, extends in a second direction (e.g., the Y-direction). Each of bit lines (e.g., first bit line 5031 and second bit line 5033) extends in the second direction. Each of word lines 505 extends in a third direction (e.g., the X-direction). The first direction is perpendicular to the second direction, and the second direction is perpendicular to the third direction. The word lines can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, the word lines may include titanium nitride.

Memory device 500 may further include a first dielectric layer 513. As shown in FIGS. 5B and 5C, at least a portion of the pairs of first air gaps 5111 and 5113 is between the adjacent bit lines. And, at least one of the pairs of first air gaps 5111 and 5113 is encapsulated by first dielectric layer 513 and a pair of the second dielectric layers 5171 and 5173. That is, some portions of first dielectric layer 513 and the pair of the second dielectric layers 5171 and 5173 may encapsulate the pairs of first air gaps 5111 and 5113, while some portions of first dielectric layer 513 may have openings on top or side of the pairs of first air gaps 5111 and 5113. In some implementations, the pairs of first air gaps 5111 and 5113 are at least partially surrounded by first dielectric layer 513 and the pair of the second dielectric layers 5171 and 5173. The pairs of first air gaps 5111 and 5113, in some implementations, may extend in the first direction (e.g., the Z-direction) in a same or similar depth of the bit lines. The pairs of first air gaps 5111 and 5113, in some implementations, may extend in the first direction (e.g., the Z-direction) to the same or similar depth of semiconductor body 501 such that the pairs of first air gaps 5111 and 5113 may be between adjacent semiconductor bodies 501. In some implementations, first dielectric layer 513 can include any suitable dielectric materials, such as silicon oxide, silicon nitride, silicon oxynitride, or high-k dielectrics. For example, first dielectric layer 513 may include silicon oxide.

In some implementations, the pair of second dielectric layers 5171, 5173 may extend in the first direction to the second end of semiconductor body 501. Each of the pair of second dielectric layers 5171, 5173 is between two adjacent semiconductor bodies 501. In some implementations, first dielectric layer 513 may also be formed between each of the pair of second dielectric layers 5171, 5173, and corresponding semiconductor body 501. In some implementations, first dielectric layer 513 may also be formed between second dielectric layers 5171 and 5173. In some implementations, the pair of second dielectric layers 5171, 5173 can include any suitable dielectric materials, such as silicon oxide, silicon nitride, silicon oxynitride, or high-k dielectrics. For example, the pair of second dielectric layers 5171, 5173 may include silicon nitride. In some implementations, the pair of second dielectric layers 5171, 5173, and first dielectric layer 513 are different dielectric materials.

Memory device 500, as shown in FIGS. 5B and 5C, may further include bit line contacts 509. Each of bit line contacts 509 is between each of bit lines (e.g., first bit line 5031 and second bit line 5033) and a corresponding semiconductor body 501. Bit line contacts 509 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, bit line contacts 509 may include doped polysilicon.

Memory device 500, as shown in FIG. 5C, may further include storage units 507 (e.g., storage unit 212 in FIG. 2). Each of storage units 507 is coupled to a second end of a corresponding semiconductor body 501 (opposite to the first end of semiconductor body 501 along the Z-direction). The second end of the semiconductor body can be, for instance, the drain end of the semiconductor body. In some implementations, each of storage units 507 is coupled to the second end of the corresponding semiconductor body 501 via a storage unit contact 515.

As shown in FIG. 5C, memory device 400 includes a first semiconductor structure 523 (e.g., first semiconductor structure 102 in FIG. 1) including the peripheral circuits of the memory cell array coupled to second semiconductor structure 521. A bonding interface can be formed between first semiconductor structure 523 and second semiconductor structure 521. In some implementations, the bonding interface may be a boundary between the memory cell array in second semiconductor structure 521 and the peripheral circuit in first semiconductor structure 523.

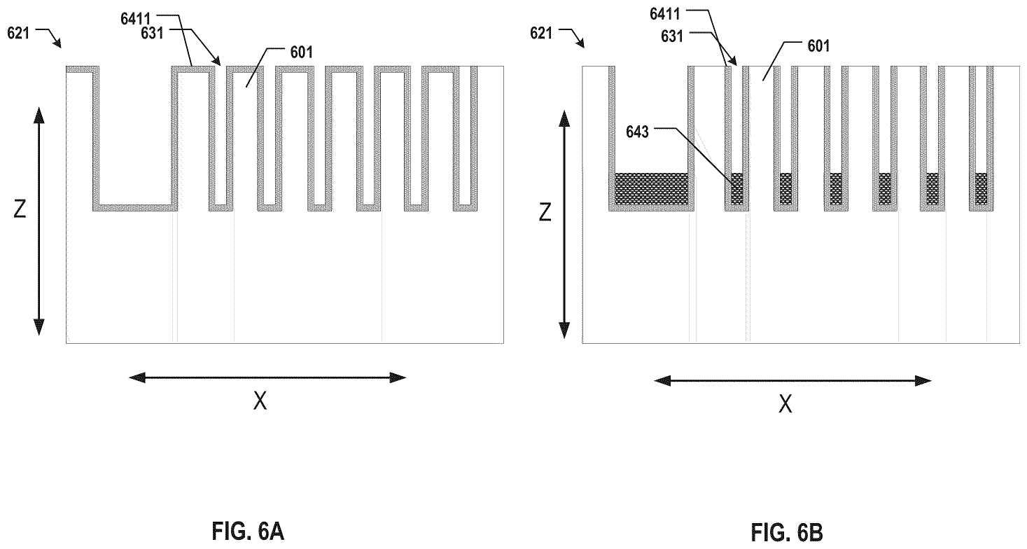

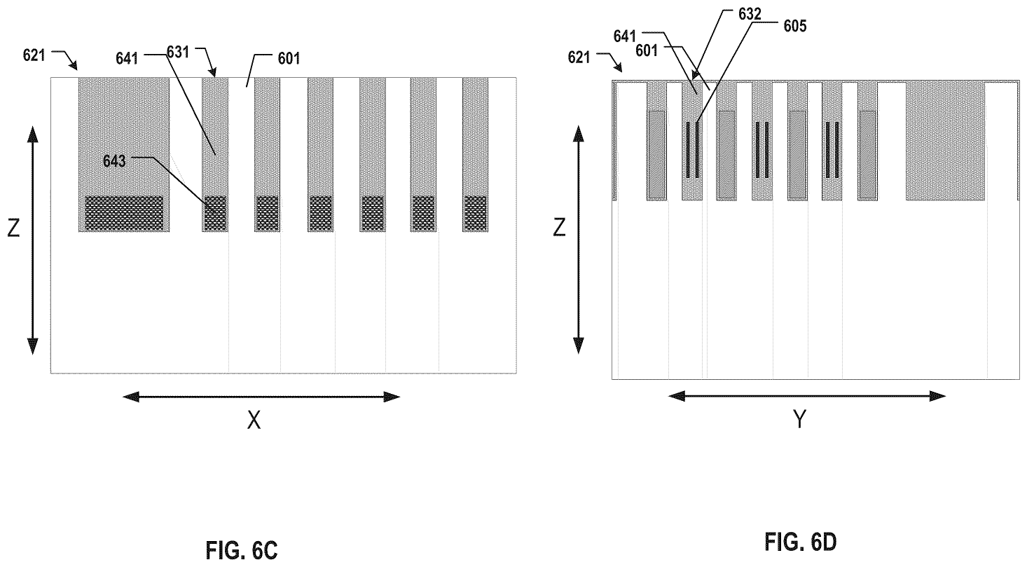

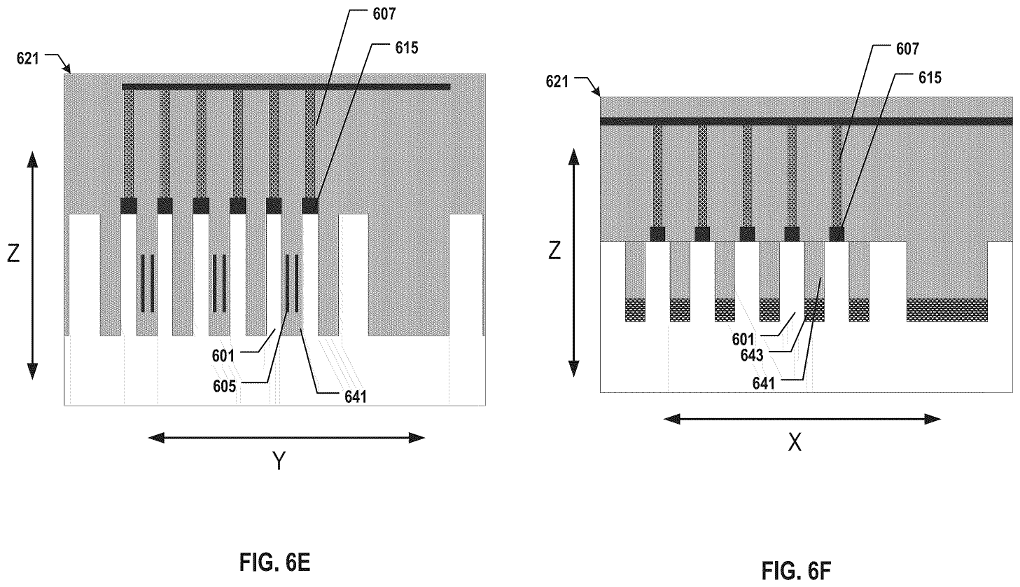

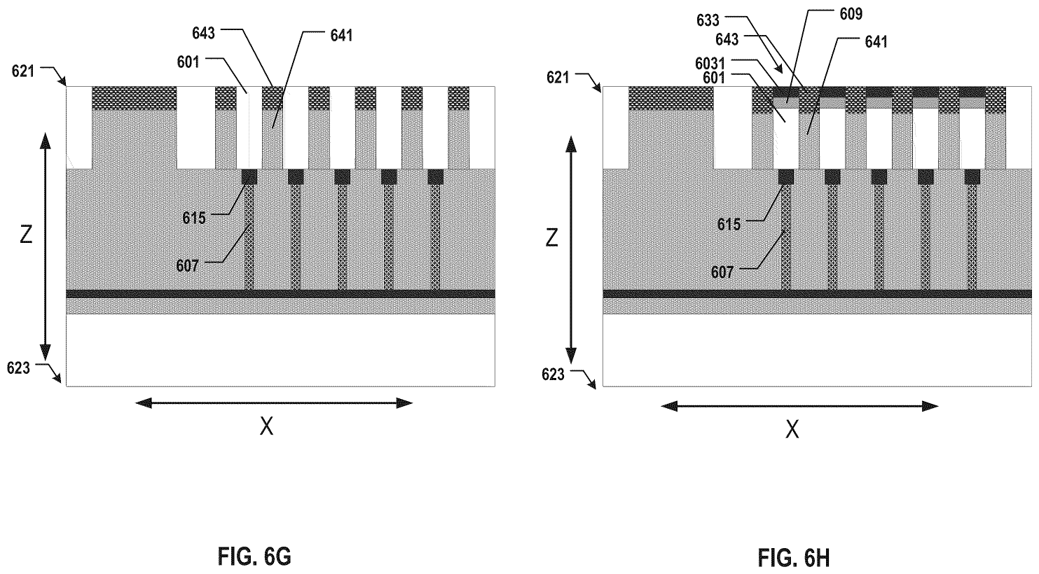

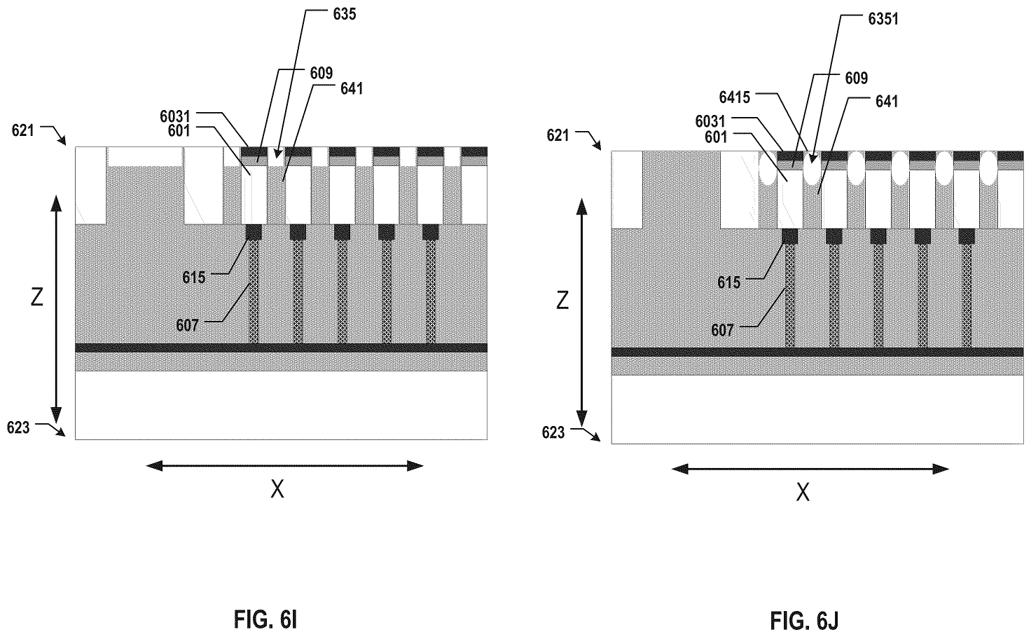

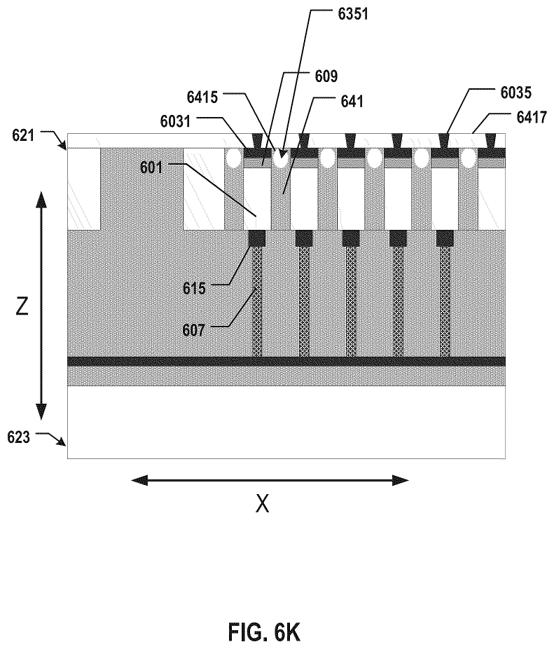

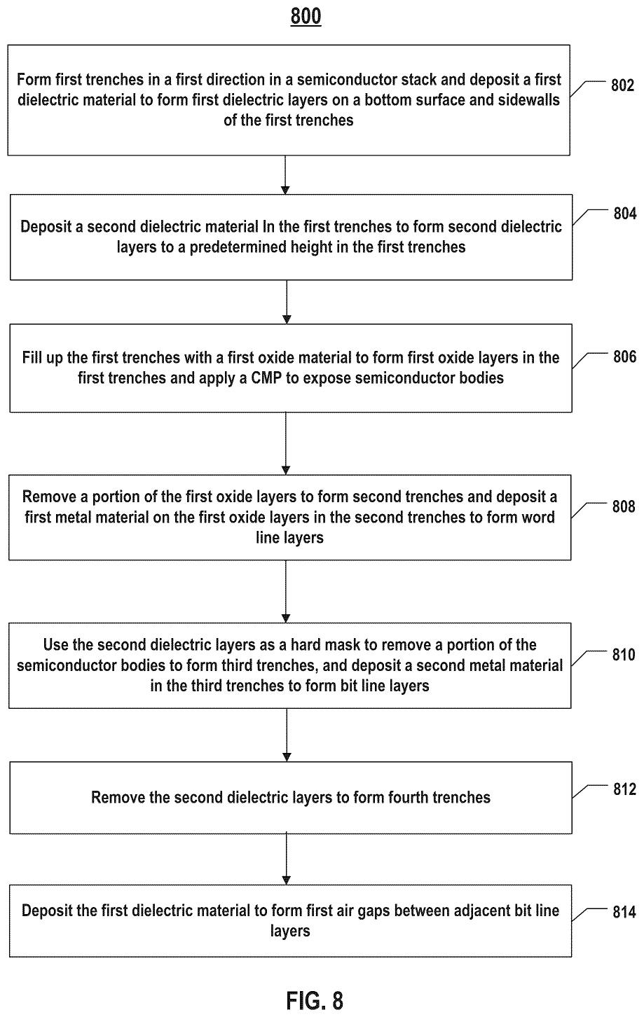

FIGS. 6A-6K illustrate a fabrication process for forming a memory device including vertical transistors, according to some aspects of the present disclosure. FIG. 8 illustrates a flowchart of a method for forming a memory device, according to some aspects of the present disclosure. For the purpose of better describing the present disclosure, the memory device in FIGS. 6A-6K and method 800 in FIG. 8 will be discussed together. It is understood that the operations shown in method 800 are not exhaustive and that other operations may be performed as well before, after, or between any of the illustrated operations. Further, some of the operations may be performed simultaneously, or in a different order than shown in FIGS. 6A-6K and method 800 in FIG. 8.

Referring to FIG. 8, method 800 starts at operation 802, in which a first semiconductor stack is provided, first trenches are formed in a first direction in the first semiconductor stack, a first dielectric material is deposited to form a first dielectric layer on a bottom surface and sidewalls of the first trenches. As shown in FIG. 6A, a portion of a first semiconductor stack 621 is removed to form first trenches 631 in a first direction (e.g., the Z-direction). Semiconductor bodies 601 are formed thereafter. First trenches 631 and semiconductor bodies 601 may extend in a second direction (e.g., the Y-direction). Next, a first dielectric material is deposited to form first dielectric layer 6411 on a bottom surface and sidewalls of first trenches 631 and also form on a first end and side surfaces of semiconductor bodies 601.

Next, referring to FIG. 8, method 800 proceeds to operation 804, in which a second dielectric material is deposited in the first trenches to form a second dielectric layer to a predetermined height in the first trenches. As shown in FIG. 6B, a second dielectric material is deposited in first trenches 631 to form second dielectric layer 643 to a predetermined height in first trenches 631. That is, second dielectric layer 643 has a first predetermined height.

Next, referring to FIG. 8, method 800 proceeds to operation 806, in which the first trenches are filled up with a first oxide material to form a first oxide layer in the first trenches and apply an etching process (e.g., a chemical mechanical polishing (CMP)) to expose semiconductor bodies. As shown in FIG. 6C, first trenches 631 are filled up with a first oxide material to form a first oxide layer 641 in first trenches 631 and apply an etching process to expose semiconductor bodies 601. In some implementations, a material of first oxide layer 641 in FIG. 6C and a first dielectric layer 6411 in FIG. 6A may be the same. As such, second dielectric layer 643 are encapsulated by first oxide layer 641 and first dielectric layer 6411 (i.e., they may be referred to as a same dielectric layer since they are the same material).

Next, referring to FIG. 8, method 800 proceeds to operation 808, in which a portion of the first oxide layer is removed to form second trenches, and a first metal material is deposited on the first oxide layer in the second trenches to form word line layers. As shown in FIG. 6D, a portion of the first oxide layer 641 is removed to form second trenches 632, and then a first metal material is deposited on the remaining first oxide layer 641 in second trenches 632 to form word line layers 605 (e.g., corresponding to 405 in FIG. 4C).

Next, as shown in FIGS. 6E and 6F, a storage unit contact 615 is formed in contact with a second end of semiconductor bodies 601 (e.g., the drain end of semiconductor bodies 601), and a storage unit 607 is formed on storage unit contact 615.

Next, as shown in FIG. 6G, a second semiconductor stack 623 is formed and coupled to first semiconductor stack 621. Second semiconductor stack 623 may be used to form first semiconductor structure 102 including the peripheral circuits of a memory cell array, as shown in FIG. 1. In some implementations, the first dielectric material is deposited on storage unit 607 to form an interlayer. And second semiconductor stack 623 (e.g., a carrier substrate) may be bonded via the interlayer after forming storage unit 607. Next, as shown in FIG. 6G, first semiconductor stack 621 is thinned to expose second dielectric layer 643 and semiconductor body 601 after bonding to the carrier substrate.

Next, referring to FIG. 8, method 800 proceeds to operation 810, in which the second dielectric layer is used as a hard mask to remove a portion of the semiconductor bodies to form third trenches, and a second metal material is deposited in the third trenches to form bit line layers. As shown in FIG. 6H, second dielectric layer 643 is used as a hard mask to remove a portion of semiconductor bodies 601 to form third trenches 633. Next, a second metal material is deposited in third trenches 633 to form bit line layers 6031. In some implementations, a bit line contact 609 is formed in third trenches 633 between bit line layers 6031 and semiconductor bodies 601. After the deposition of bit line layers 6031, another etching process, e.g., a CMP, may be applied to remove additional second metal material over second dielectric layer 643.

Next, referring to FIG. 8, method 800 starts at operation 812, in which the second dielectric layer is removed to form fourth trenches. As shown in FIG. 6I, second dielectric layer 643 is removed to form fourth trenches 635, and first oxide layer 641 are exposed. Since the first predetermined height of second dielectric layer is larger than a first depth of bit line layers 6031, after the removal of second dielectric layer 643, fourth trenches 635 may extend in the first direction (e.g., the Z-direction) into a second depth more than the first depth of bit line layers 6031.

Next, referring to FIG. 8, method 800 proceeds to operation 814, in which the first dielectric material is deposited to form first air gaps between adjacent bit line layers. As shown in FIG. 6J, the first dielectric material is deposited to form second oxide layers 6415 and to form first air gaps 6351 between adjacent bit line layers 6031. In some implementations, second oxide layers 6415 and first oxide layer 641 are the same materials (e.g., the first dielectric material). That is, they may be referred as a same dielectric layer since they are the same material. For example, they can be referred as first dielectric layer 413 shown in FIGS. 4B and 4C.

Next, as shown in FIG. 6K, the first dielectric material is deposited on bit line layers 6031 to form third oxide layer 6417, and then a bit line outgoing structure 6035 is formed in contact with bit line layers 6031 via trenches in third oxide layer 6417. In some implementations, third oxide layer 6417 and first oxide layer 641 are the same materials (e.g., the first dielectric material).

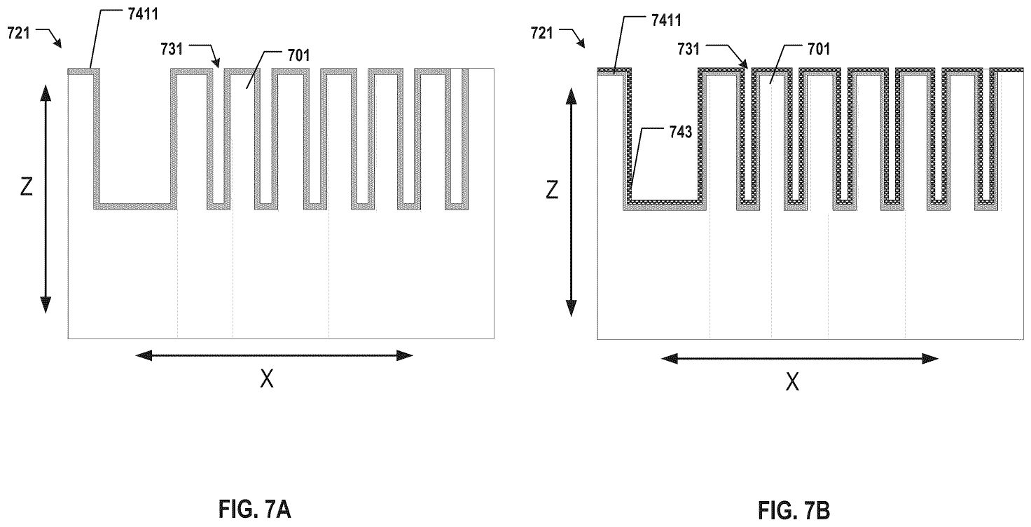

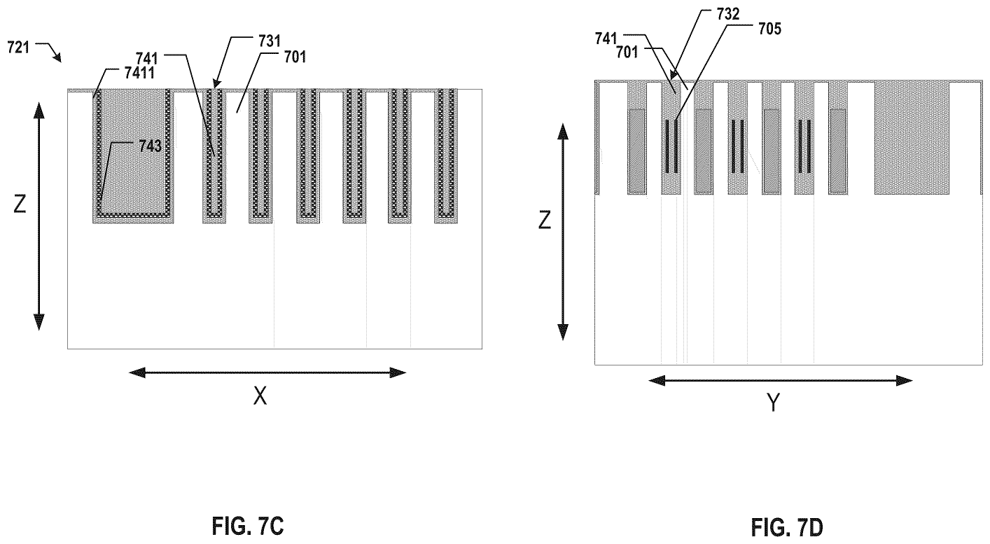

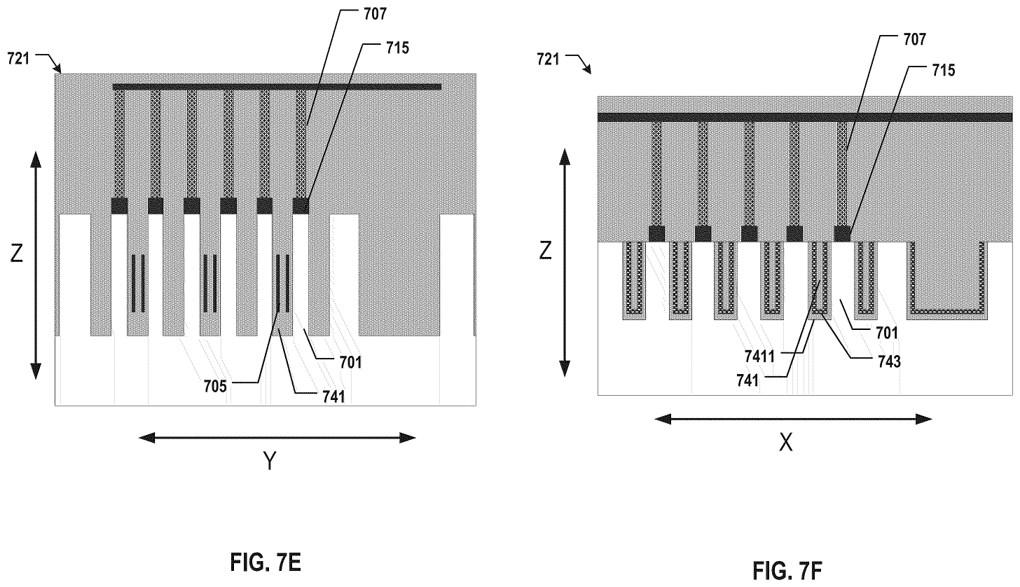

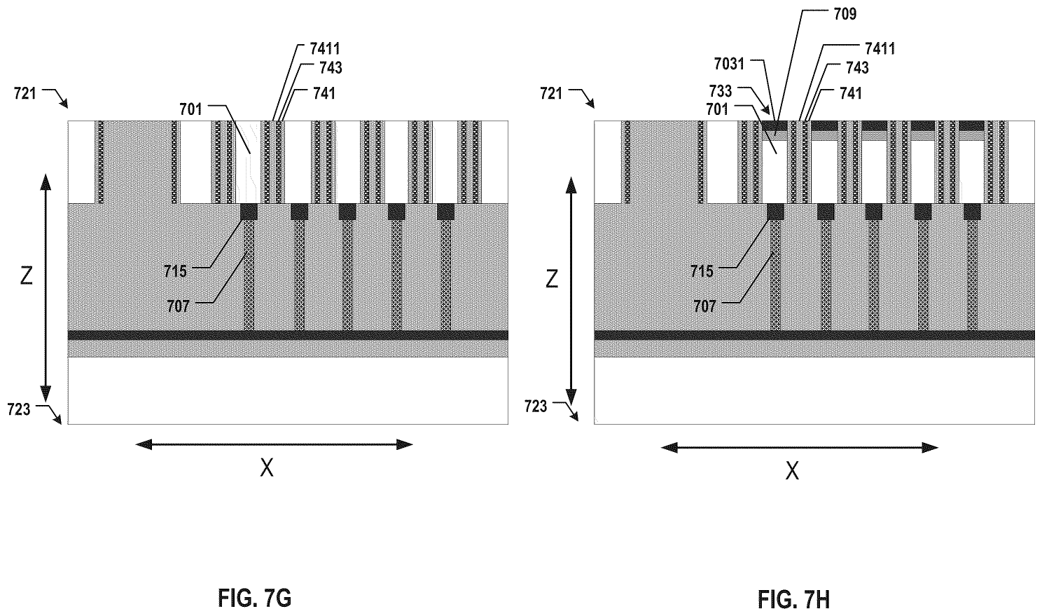

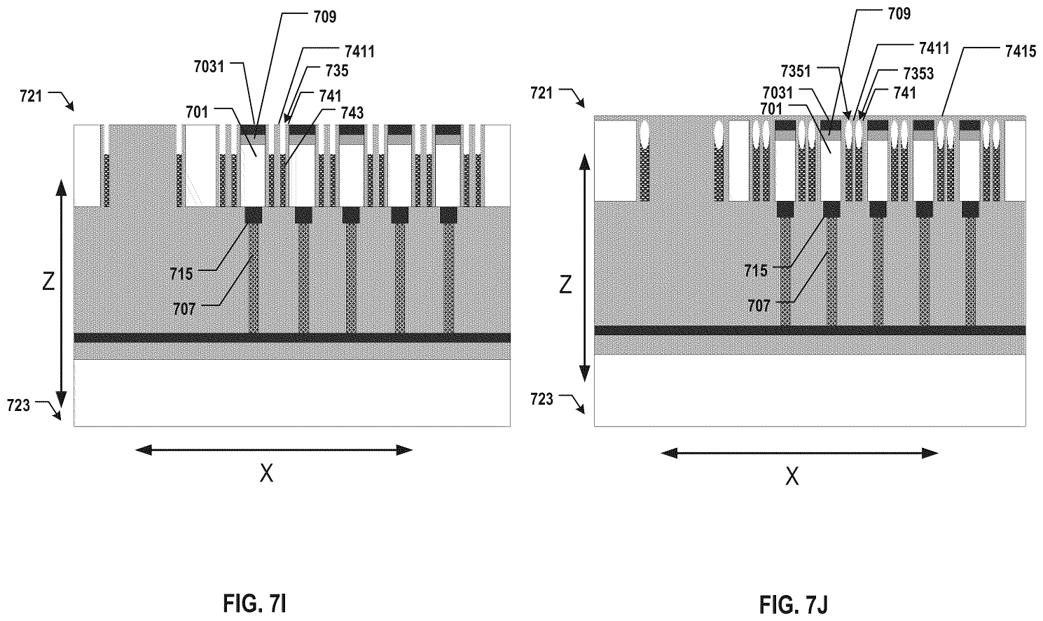

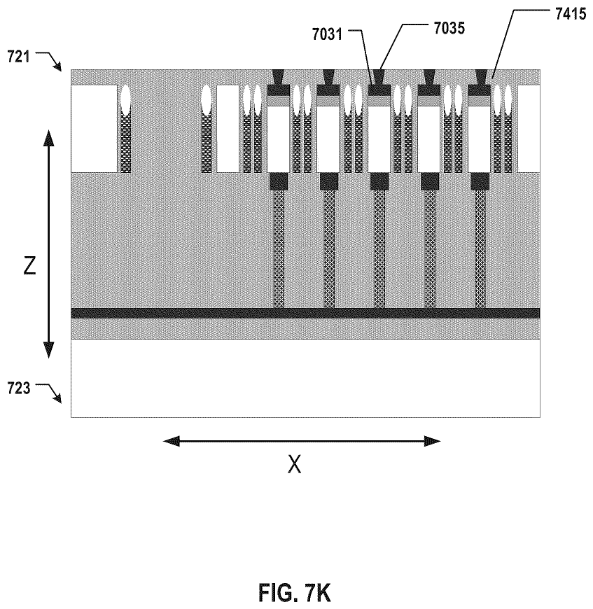

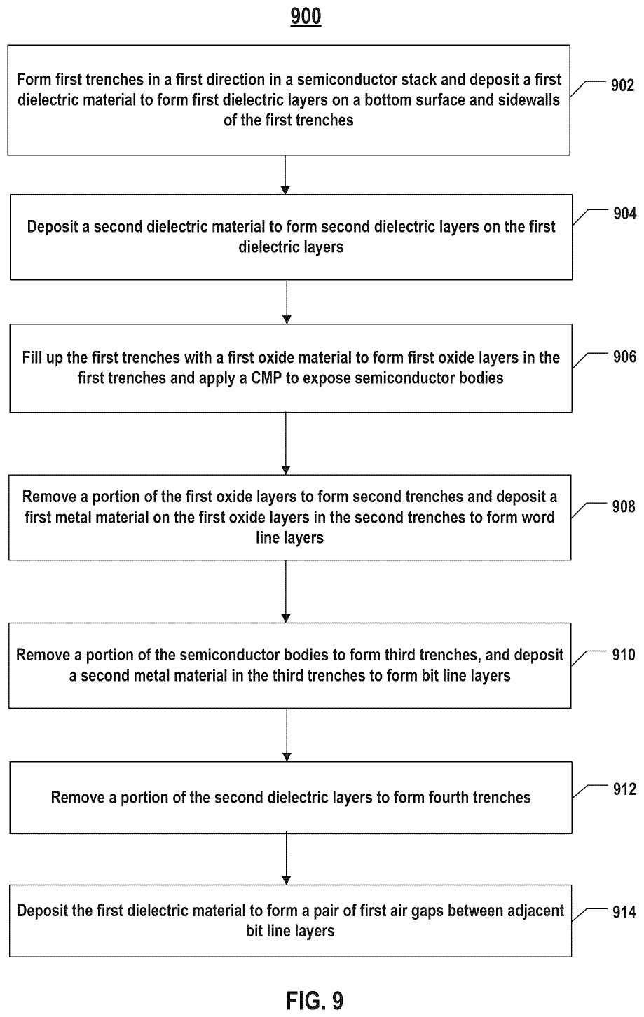

FIGS. 7A-7K illustrate a fabrication process for forming a memory device including vertical transistors, according to some aspects of the present disclosure. FIG. 9 illustrates a flowchart of a method for forming a memory device, according to some aspects of the present disclosure. For the purpose of better describing the present disclosure, the memory device in FIGS. 7A-7K and method 900 in FIG. 9 will be discussed together. It is understood that the operations shown in method 900 are not exhaustive and that other operations may be performed as well before, after, or between any of the illustrated operations. Further, some of the operations may be performed simultaneously, or in a different order than shown in FIGS. 7A-7K and method 900 in FIG. 9.

Referring to FIG. 9, method 900 starts at operation 902, in which a first semiconductor stack is provided, first trenches are formed in a first direction in the first semiconductor stack, a first dielectric material is deposited to form a first dielectric layer on a bottom surface and sidewalls of the first trenches. As shown in FIG. 7A, a portion of a first semiconductor stack 721 is removed to form first trenches 731 in a first direction (e.g., the Z-direction). Semiconductor bodies 701 are formed thereafter. First trenches 731 and semiconductor bodies 701 may extend in a second direction (e.g., the Y-direction). Next, a first dielectric material is deposited to form first dielectric layer 7411 on a bottom surface and sidewalls of first trenches 731 and also form on a first end and side surfaces of semiconductor bodies 701.

Next, referring to FIG. 9, method 900 proceeds to operation 904, in which a second dielectric material is deposited to form a second dielectric layer on the first dielectric layer. As shown in FIG. 7B, a second dielectric material is deposited on first trenches 731 and semiconductor bodies 701 to form second dielectric layer 743 on first dielectric layer 7411. That is, second dielectric layer 743 is formed uniformly on first dielectric layer 7411. The second dielectric material is different from the first dielectric material.

Next, referring to FIG. 9, method 900 proceeds to operation 906, in which the first trenches are filled up with a first oxide material to form first oxide layer in the first trenches and apply an etching process (e.g., a chemical mechanical polishing (CMP)) to expose semiconductor bodies. As shown in FIG. 7C, first trenches 731 are filled up with a first oxide material to form first oxide layer 741 in first trenches 731 and apply an etching process to expose semiconductor bodies 701. In some implementations, the material of first oxide layer 741 and first dielectric layer 7411 may be the same, while the material of first oxide layer 741 and second dielectric layer 743 may be different. As such, in some implementations, second dielectric layer 743 is encapsulated by first oxide layer 741 and first dielectric layer 7411 (i.e., they may be referred to as a same dielectric layer since they are the same material).

Next, referring to FIG. 9, method 900 proceeds to operation 908, in which a portion of the first oxide layer is removed to form second trenches, and a first metal material is deposited on the first oxide layer in the second trenches to form word line layers. As shown in FIG. 7D, a portion of the first oxide layer 741 is removed to form second trenches 732, and then a first metal material is deposited on the remaining first oxide layer 741 in second trenches 732 to form word lines 705 (e.g., corresponding to 505 in FIG. 5C).

Next, as shown in FIGS. 7E and 7F, a storage unit contact 715 is formed in contact with a second end of semiconductor bodies 701 (e.g., the drain end of semiconductor bodies 701), and a storage unit 707 is formed on storage unit contact 715.

Next, as shown in FIG. 7G, a second semiconductor stack 723 is formed and coupled to first semiconductor stack 721. Second semiconductor stack 723 may be used to form first semiconductor structure 102 including the peripheral circuits of a memory cell array, as shown in FIG. 1. In some implementations, the first dielectric material is deposited on storage unit 707 to form an interlayer. And second semiconductor stack 723 (e.g., a carrier substrate) may be bonded via the interlayer after forming storage unit 707. Next, as shown in FIG. 7G, first semiconductor stack 721 is thinned to expose second dielectric layer 743, first oxide layer 741, first dielectric layer 7411, and semiconductor body 701 after bonding to the carrier substrate.

Next, referring to FIG. 9, method 900 proceeds to operation 910, in which a portion of the semiconductor bodies is removed to form third trenches, and a second metal material is deposited in the third trenches to form bit line layers. As shown in FIG. 7H, a portion of semiconductor bodies 701 is removed to form third trenches 733. Next, a second metal material is deposited in third trenches 733 to form bit line layers 7031. In some implementations, a bit line contact 709 is formed in third trenches 733 between bit line layers 7031 and semiconductor bodies 701. After the deposition of bit line layers 7031, another etching process, e.g., a CMP, may be applied to remove additional second metal material over second dielectric layer 743, first oxide layer 741, and first dielectric layer 7411.

Next, referring to FIG. 9, method 900 proceeds to operation 912, in which a portion of the second dielectric layer is removed to form fourth trenches. As shown in FIG. 7I, a portion of second dielectric layer 743 is removed to form fourth trenches 735 between first oxide layer 741 and first dielectric layer 7411. After the removal of a portion of second dielectric layer 743, fourth trenches 735 may extend in the first direction (e.g., the Z-direction) into a second depth more than the first depth of bit line layers 7031.

Next, referring to FIG. 9, method 900 proceeds to operation 914, in which the first dielectric material is deposited to form a pair of first air gaps between adjacent bit line layers. As shown in FIG. 7J, the first dielectric material is deposited to form second oxide layers 7415 and to form a pair of first air gaps 7351 and 7353 between adjacent bit line layers 7031. In some implementations, second oxide layers 7415 and first oxide layer 741 are the same materials (e.g., the first dielectric material). That is, they may be referred as a same dielectric layer since they are the same material. For example, they can be referred to as first dielectric layer 513 shown in FIGS. 5B and 5C.

Next, as shown in FIG. 7K, the first dielectric material is deposited on bit line layers 7031 to form third oxide layer 7415, and then a bit line outgoing structure 7035 is formed in contact with bit line layers 7031 via trenches in third oxide layer 7415. In some implementations, third oxide layer 7415 and first oxide layer 741 are the same materials (e.g., the first dielectric material).

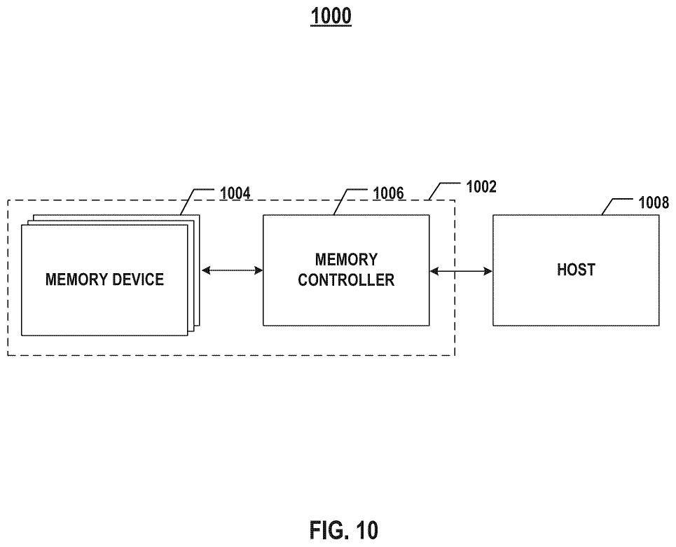

FIG. 10 illustrates a block diagram of an example system 1000 having a memory device, according to some aspects of the present disclosure. System 1000 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 10, system 1000 can include a host 1008 and a memory system 1002 having one or more memory devices 1004 and a memory controller 1006. Host 1008 can be a processor of an electronic device, such as a central processing unit (CPU), or a system-on-chip (SoC), such as an application processor (AP). Host 1008 can be configured to send or receive the data to or from memory devices 1004.

Memory device 1004 can be any memory devices disclosed herein, such as memory devices 100, 101, 200, 400, or 500. In some implementations, memory device 1004 includes an array of memory cell arrays each including a vertical transistor, as described above in detail.

Memory controller 1006 is coupled to memory device 1004 and host 1008 and is configured to control memory device 1004, according to some implementations. Memory controller 1006 can manage the data stored in memory device 1004 and communicate with host 1008. Memory controller 1006 can be configured to control operations of memory device 1004, such as read, write, and refresh operations. Memory controller 1006 can also be configured to manage various functions with respect to the data stored or to be stored in memory device 1004 including, but not limited to refresh and timing control, command/request translation, buffer and schedule, and power management. In some implementations, memory controller 1006 is further configured to determines the maximum memory capacity that the computer system can use, the number of memory banks, memory type and speed, memory particle data depth and data width, and other important parameters. Any other suitable functions may be performed by memory controller 1006 as well. Memory controller 1006 can communicate with an external device (e.g., host 1008) according to a particular communication protocol. For example, memory controller 1006 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

The foregoing description of the specific implementations can be readily modified and/or adapted for various applications. Therefore, such adaptations and modifications are intended to be within the meaning and range of equivalents of the disclosed implementations, based on the teaching and guidance presented herein. The breadth and scope of the present disclosure should not be limited by any of the above-described exemplary implementations, but should be defined only in accordance with the following claims and their equivalents.

What is claimed is:

1. A semiconductor device comprising:
an array of memory cells, wherein each of the memory cells comprises a vertical transistor, wherein the vertical transistor comprises a semiconductor body extends in a first direction;
bit lines coupled to the memory cells, wherein each of the bit lines is electrically connected to a first end of the semiconductor body; and
first air gaps, wherein at least one of the first air gaps is between adjacent bit lines.

2. The semiconductor device of claim 1, wherein at least two of adjacent first air gaps are between adjacent bit lines.

3. The semiconductor device of claim 1, further comprising:
word lines coupled to the memory cells, wherein each of the word lines is electrically connected to the gate structure.

4. The semiconductor device of claim 3, wherein:
each of the first air gaps extends in a second direction, each of the bit lines extends in the second direction, and each of the word lines extends in a third direction; and
the first direction is perpendicular to the second direction, and the second direction is perpendicular to the third direction.

5. The semiconductor device of claim 1, further comprising:
a first dielectric layer, wherein at least a portion of the first dielectric layer is between adjacent bit lines.

6. The semiconductor device of claim 1, further comprising:
a first dielectric layer, wherein at least a portion of the first dielectric layer is between two adjacent first air gaps.

7. The semiconductor device of claim 1, further comprising:
a first dielectric layer, wherein at least one of the first air gaps is encapsulated by the first dielectric layer.

8. The semiconductor device of claim 1, further comprising:
second dielectric layers extending in the first direction, wherein each of the second dielectric layers is between two adjacent semiconductor bodies.

9. The semiconductor device of claim 1, further comprising:
a first dielectric layer; and
second dielectric layers, wherein at least a portion of the first dielectric layer is between adjacent second dielectric layers.

10. The semiconductor device of claim 9, wherein at least one of the first air gaps is encapsulated by the first dielectric layer and one of the second dielectric layers.

11. The semiconductor device of claim 1, further comprising:
a first dielectric layer, wherein only one first air gap is between adjacent bit lines, and the first air gap is encapsulated by the first dielectric layer.

12. A method for manufacturing a semiconductor device, comprising:
removing a portion of a semiconductor stack to form first trenches in a first direction and semiconductor bodies;
depositing a first dielectric material to form a first dielectric layer on a bottom surface and sidewalls of the first trenches;
depositing a second dielectric material in the first trenches to form a second dielectric layer to a predetermined height of the first trenches;
filling up the first trenches with a first oxide material to form a first oxide layer in the first trenches;
applying an etching process to expose the semiconductor body;
removing the second dielectric layer to form third trenches; and
depositing the first dielectric material to form first air gaps.

13. The method of claim 12, further comprising:
removing a portion of the first oxide layer to form second trenches; and
depositing a first metal material on the first oxide layer in the second trenches to form word line layers.

14. The method of claim 12, further comprising:
removing a portion of the semiconductor bodies to form fourth trenches; and
depositing a second metal material in the fourth trenches to form bit line layers.

15. The method of claim 14, wherein the predetermined height of the first trenches is larger than a first depth of the bit line layers.

16. The method of claim 14, wherein removing the second dielectric layer to form third trenches comprises:
removing the second dielectric layer to a second depth, wherein the second depth is larger than a first depth of the bit line layers.

17. A method for manufacturing a semiconductor device, comprising:
removing a portion of a semiconductor stack to form first trenches in a first direction and semiconductor bodies;
depositing a first dielectric material to form a first dielectric layer on a bottom surface and sidewalls of the first trenches;
depositing a second dielectric material to form a second dielectric layer on the first dielectric layer;
filling up the first trenches with a first oxide material to form a first oxide layer in the first trenches;
applying an etching process to expose the semiconductor body;
removing a portion of the second dielectric layer to form third trenches; and
depositing the first dielectric material to form first air gaps.

18. The method of claim 17, further comprising:
removing a portion of the first oxide layer to form second trenches; and
depositing a first metal material on the first oxide layer in the second trenches to form word line layers.

19. The method of claim 17, further comprising:
removing a portion of the semiconductor bodies to form fourth trenches; and
depositing a second metal material in the fourth trenches to form bit line layers.

20. The method of claim 19, wherein removing a portion of the second dielectric layer to form third trenches comprises:
removing the second dielectric layer to a second depth, wherein the second depth is larger than a first depth of the bit line layers.
